(19) United States
(12) Patent Application Publication
(10) Pub. No.: US 2012/0007170 A1
(43) Pub. Date: Jan. 12, 2012

(54) High source to drain breakdown voltage vertical field effect transistors

(76) Inventor: Chao-Cheng Lu, Taipei (TW)

(21) Appl. No.: 12/803,864

(22) Filed: Jul. 9, 2010

(51) Int. Cl. H01L 29/78

(52) U.S. Cl. 257/330; 257/E29.262

(57) ABSTRACT

An increase source to drain breakdown voltage vertical channel transistors device having a structure that is similar to that of a conventional metal oxide semiconductor field effect transistor (MOSFET), in that it includes a source, a drain, a gate and a body. According the N+N− and P+P− junction theory of semiconductor, add to N− junction between the source N+ junction to P junction of N-Channel MOSFET; add to P− junction between the source P+ junction to n junction of P-Channel MOSFET; With the proposed MOSFET of which the source to drain breakdown voltage are increase may be achieved.

### BACKGROUND OF THE INVENTION

1. Field of the Invention

The present invention relate to high source to drain breakdown voltage vertical field effect transistors, has N-Channel vertical field effect transistors comprises a N+ junction of source, a N− junction, a P junction, a N− junction, a N+ junction of drain, and a gate, wherein the N+ junction of source, N− junction, and P junction, so as to form a body diode; According to N+N−P junction theory of semiconductors, may be achieved high source to drain breakdown voltage.

The present invention relate to high source to drain breakdown voltage vertical field effect transistors, has P-Channel vertical field effect transistors comprises a P+ junction of source, a P− junction, a N junction, a P− junction, a P+ junction of drain, and a gate, wherein the P+ junction of source, P− junction, and N junction, so as to form a body diode; According to P+P−N junction theory of semiconductors, may be achieved high source to drain breakdown voltage.

2. Description of Related Art

As shown in FIG. 1, illustrates a cross-sectional view of a first prior arc N-Channel MOSFET, as shown, the N-Channel MOSFET comprises a N+ junction of source, and a P N−N+ diode, wherein N+ junction of source and P junction together connected to source of N-Channel MOSFET, so as to a first body diode BD1, and connected to source and drain of N-Channel MOSFET.

As shown in FIG. 2, illustrates a cross-sectional view of a second prior arc N-Channel MOSFET, as shown, the N-Channel MOSFET comprises a N+ junction of source, and P junction as to form a second body diode BD2, a P N− junction and N+ junction of drain as to form a third body diode BD3, the N+ junction of second body diode BD2, and N+ junction of third body diode BD3 connected to source and drain of N-Channel MOSFET.

### SUMMARY OF THE INVENTION

In order to high source to drain breakdown voltage, the present invention is proposed the following object:

The first object of the present invention to provide N− junction between the N+ junction of source and P junction of N-Channel MOSFET, may be achieved high source to drain breakdown voltage.

The second object of the present invention to provide P− junction between the P+ junction of source and N junction of P-Channel MOSFET, may be achieved high source to drain breakdown voltage.

The third object of the present invention may be achieved source to drain breakdown voltage equal drain to source breakdown voltage, as to form a unidirectional switch.

According to the defects of the prior art technology discussed above, a novel solution, the high source to drain breakdown voltage in the present invention, which provides higher efficiency in synchronous rectification, or switch function of circuit.

### BRIEF DESCRIPTION OF THE DRAWINGS

FIG. 1 illustrates a cross-sectional view of a first prior art N-Channel MOSFET.

FIG. 2 illustrates a cross-sectional view of a second prior art N-Channel MOSFET.

FIG. 3 illustrates a cross-sectional view of a N-Channel MOSFET of the present invention

FIG. 4 illustrates a cross-sectional view of a P-Channel MOSFET of the present invention.

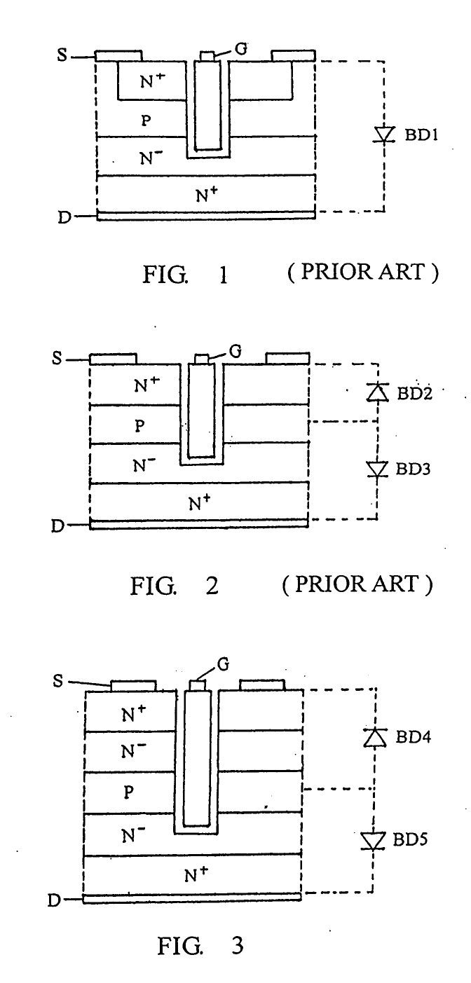

### DETAILED DESCRIPTION OF THE PREFERRED EMBODIMENTS

FIG. 3 illustrates a cross-sectional view of a N-Channel MOSFET of the present invention, as shown, source S of the N-Channel MOSFET connected to N+ junction, N+ junction connected to N− junction, N− junction connected to P junction, the N+N−P junction as to form a fourth body diode BD4; Drain D of the N-Channel MOSFET connected to N+ junction, N+ junction connected to N− junction, N− junction connected to P junction, the N+N−P junction as to form a fifth body diode BD5; As shown, the P junction is common junction of the fourth body diode BD4 and fifth body diode BD5; According to a semiconductor theory that a breakdown voltage of a N-P junction is relate to the doping concentration and the depth of the N+ junction of source of N-Channel MOSFET and the N− junction drift region, and thus the N+ junction and the N− junction drift region of the present invention can be used increase the breakdown voltage; In the structures of the present invention, the doping concentration and the depth of the N+ junction and the N− junction drift region can be suitably varied according to a predetermined value of the breakdown voltage without limitation.

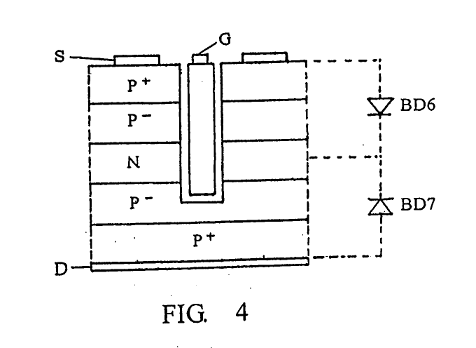

FIG. 4 illustrates a cross-sectional view of a P-Channel MOSFET of the present invention, as shown, source S of the P-Channel MOSFET connected to P+ junction, P+ junction connected to P− junction, P− junction connected to N junction, the P+P−N junction as to form a sixth body diode BD6; Drain D of the P-Channel MOSFET connected to P+ junction, P+ junction connected to P− junction, P− junction connected to N junction, the P+P−N junction as to form a seventh body diode BD7; As shown, the N junction is common junction of the sixth body diode BD6 and seventh body diode BD7; According to a semiconductor theory that a breakdown voltage of a P-N junction is relate to the doping concentration and the depth of the P+ junction of source of P-Channel MOSFET and the P− junction drift region, and thus the P+ junction and the P− junction drift region of the present invention can be used increase the breakdown voltage; In the structures of the present invention, the doping concentration and the depth of the P+ junction and the P− junction drift region can be suitably varied according to a predetermined value of the breakdown voltage without limitation.

While the invention has been described with respect to specific embodiments by way of illustration, many modification and changes will occur to those skilled in the art. It is therefore, to be understood that the append claims are intended to cover all such modifications and changes as fall within the true spirit and scope of the invention.

What is claimed is:

1. A high source to drain breakdown voltage vertical field effect transistors having a body diode, said a body diode comprising:
a N+ junction, connected to source of N-Channel MOSFET;
a N− junction, connected to N+ junction; and
a P junction, connected to N− junction.

2. A high source to drain breakdown voltage vertical field effect transistors having a body diode, said a body diode comprising:
a P+ junction, connected to source of P-Channel MOSFET;
a P− junction, connected to P+ junction; and
a N junction, connected to P− junction.
